(19) United States
(12) Patent Application Publication
(10) Pub. No.: US 2012/0013348 A1
(43) Pub. Date: Jan. 19, 2012

(54) TEST FIXTURE FOR TESTING SEMICONDUCTOR DIE WITH ITS LOADING MEMBER MAINTAINED FLAT THROUGHOUT THE TEST

(75) Inventors: Cheng-Huiung Chen, Kuei-Shan Hsiang (TW); Chia-Bin Tseng, Kuei-Shan Hsiang (TW)

(73) Assignee: CHROMA ATE INC., Kuei-Shan Hsiang (TW)

(21) Appl. No.: 12/896,899

(22) Filed: Oct. 3, 2010

(30) Foreign Application Priority Data
Jul. 16, 2010 (TW) 99123485

(51) Int. Cl. G01R 31/26

(52) U.S. Cl. 324/555

(57) ABSTRACT

A test fixture for testing a semiconductor die with its loading member maintained flat throughout the test is disclosed. The test fixture includes a loading member and a frame. The loading member includes a base film having a melting point higher than a thermal equilibrium temperature thereof, wherein the thermal equilibrium temperature is achieved due to heat transfer from the semiconductor die under test to the base film via the adhesive layer. The loading member further includes an adhesive layer made of electrically conductive adhesive material. The loading member is adapted for securing diced LED dies in position and maintained flat throughout the die testing process, thereby ensuring the accuracy of testing for optical and electrical properties of the dies.

### FIELD OF THE INVENTION

The present invention relates to a test fixture for testing a semiconductor die, and more particularly, to a test fixture having a loading member maintained flat throughout the testing of a semiconductor die.

### DESCRIPTION OF THE RELATED ART

A light-emitting diode (LED) is an electroluminescent semiconductor device, which means that when an electrical current is applied to it, a voltage difference will occur between two electrodes and energy is generated due to the combination of electrons and holes. Some of the energy thus generated is released in the form of light, and the rest is converted into heat energy. With LEDs being widely utilized in a variety of applications, there exists an increasing need for LEDs with higher brightness. The employment of materials having higher electric-optical conversion efficiency is probably the most effective way to enhance brightness, other than increasing working power. However, suitable materials can only be attained by chance, so that any improvement thereon is highly unpredictable and often limited. On the other hand, the increment of working power would immediately result in an overheat problem due to thermal resistance.

During the die fabrication process which is typically classified into the LED midstream industry, it is known that the excess heat generated due to thermal resistance could adversely affect the accuracy of testing for the optical and electrical properties of dies. FIG. 1 shows a conventional method for die fabrication and testing, in which a die 90 is provided with two electrodes 900, 901 formed on the same side of the die 90. Next, after the completion of layout design, an entire wafer 9 is diced as shown in FIG. 2 by, for example, laser dicing. The wafer 9, which is diced but not all the way through its thickness, is placed onto and supported by a blue tape 8, so that the wafer 9 is intimately attached to a blue tape adhesive layer 80 coated on the blue tape 8. The blue tape 8 is then tightly stretched and fixed onto a frame 11. Owing to the expandability of the blue tape 8, the wafer 9 adhered on the blue tape 8 is divided along the dicing lines and separated into individual dies 90, while the dies 90 remain temporarily adhered on the blue tape 8. This is a typical process for separating multiple dies 90 from a wafer.

During the test, as shown in FIG. 3, two probe elements 70 are brought into contact with the two electrodes disposed on the same side of the die 90, so that the die 90 under test is powered to emit light. Test data, such as the brightness and optical field distribution of the emitted light, are collected by an optical sensor, such as a charge-coupled device (CCD) or a solar cell, from which the quality of the die 90 can be evaluated. After the test, the test data are recorded and stored in a processing device 73 for subsequent sorting process.

In order to satisfy different needs, dies are designed differently from one to another. FIG. 4 illustrates a commonly used high-brightness die 90′, whose light-emitting face is only provided with a single electrode to maximize the light-emitting area, while the other electrode is installed on the face opposite to the light-emitting face. For clarity purpose, the electrode provided on the light-emitting face and the electrode formed on the face opposite to the light-emitting face are referred herein to as an upper electrode 900′ and a lower electrode 901′, respectively. The die 90″ of this type, in which two electrodes are provided on opposite faces, is referred to as a semiconductor die with electrodes on separate faces. In this design, the lower electrode may be configured in approximately the same size as the die face and further welded to a solder pad formed on a circuit board disposed beneath the die, thereby facilitating heat dissipation of the die via the circuitry of the circuit board.

A frequently used process for testing the die of FIG. 4 is illustrated in FIG. 5, where a wafer 9′ is placed on a single electrically conductive unit 72′ though which all of the lower electrodes are grounded. The respective dies 90′ (represented by a single die 90′ in FIG. 5) of the wafer 9′ are powered, one at a time, by a single probe element 70′. These dies 90′ are then diced and separated from one another after testing. These steps could be carried out in different sequence, for example, by first dicing the wafer 9′ into individual dies 90′ and then testing each die separately. However, when the to-be-separated dies 90′, each including two electrodes on different faces, are placed and adhered onto a blue tape as described above and separated from one another by stretching the blue tape, the probe element has to punch through the blue tape from the underside of the tape, so as to reach the lower electrodes of the dies 90′ adhered to the electrically non-conductive blue tape and carry out testing. The punched portions of the blue tape will gradually expand due to stress concentration, causing deterioration of the flatness of the blue tape. The flatness of the blue tape could get worse as a result of melting of the probe electrode that punches through the blue tape due to temperature rise when electrical current is flowing through. Some of the dies supported by the blue tape may consequently become so tilted as to cause a change in the emitting angle of light, which may in turn cause the optical sensor to collect an incorrect measurement result.

A primary purpose of testing individual dies is to obtain the test data regarding the optical and electrical properties of each die. However, the poor electrical/thermal conductivity and the poor thermal tolerance of the blue tape are detrimental to this purpose in terms of the following aspects:

1. In the case where multiple high-power LED dies are supported by the blue tape and supplied with power, the elevated temperature generated by the LED dies would cause the adhesive layer coated on the blue tape to become so sticky that residual adhesives will stay on the tested LED dies after these LED dies are peeled off from the blue tape. This will cause serious trouble for subsequent packaging process and significantly reduce the product yield of the finished LED devices.

2. A partially molten blue tape often creates warping and results in loss of flatness. Some of the LED dies supported thereon may consequently become so tilted as to change the light emitting angle and cause incorrect measurement results.

3. After an LED die are powered to emit light, the junction temperature of the LED die is severely affected due to poor thermal conductivity of the blue tape, which in turn interferes with the color appearance, emission spectrum, brightness, color temperature and voltage-current characteristics of the LED die. Such a temperature variation during the test would unfavorably reduce the accuracy of test results and further hamper the subsequent die sorting process, causing quality control problems.

Therefore, there exists a need for a die carrier that exhibits better tolerance to high temperature and has higher thermal conductivity as compared to the conventional counterparts, so as to prevent the die carrier from warping and prevent residual adhesives from sticking to the tested dies. Preferably, the thermal conductivity of the die carrier is so high as to maintain thermal equilibrium of the dies during test, whereby the temperature during the test is kept within a predetermined range. The invention allows accurate testing and sorting of dies, thereby improving the automatic testing throughput and productivity. The invention is advantageous in reducing the testing time and saving the testing cost, and all of these will be reflected in profits and competiveness of the firm and also in customers' satisfaction to the end products.

### SUMMARY OF THE INVENTION

Accordingly, an object of the present invention is to provide a loading member for testing a semiconductor die, which is maintained flat throughout the test to ensure accuracy of the test results.

Another object of the invention is to provide a test fixture for testing a semiconductor die, which is effective in preventing residual adhesives from sticking to the tested dies, thereby improving the product yield in the subsequent packaging process.

It is still another object of the invention to provide a test fixture for testing a semiconductor die, which exhibits an elevated thermal conductivity to allow the die under test to achieve thermal equilibrium as soon as possible, whereby the die is accurately tested at a predetermined operation temperature.

It is still another object of the invention to provide a loading member for testing a semiconductor die, which is advantageous in improving the accuracy of testing for optical and electrical properties of the semiconductor die.

The present invention therefore provides a test fixture for testing a semiconductor die, with its loading member maintained flat throughout the test. The test fixture is adapted for carrying a plurality of semiconductor dies to be tested by being supplied with electric power. The test fixture comprises a loading member and a frame for tightly stretching and fixing the loading member in position. The loading member includes an adhesive layer for adhering thereon the semiconductor die and a base film having a melting point substantially higher than a thermal equilibrium temperature thereof, wherein the thermal equilibrium temperature of the base film is achieved due to heat transfer from the semiconductor die under test to the base film via the adhesive layer.

The test fixture for testing a semiconductor die as disclosed herein is made of a loading member composed of a base film and an adhesive layer, and a frame for securing and tightly stretching the loading member. The base film is made of polymeric material with high expandability, high strength and high tolerance to heat. During use, the base film can readily tolerate the heat transferred from an LED die via the adhesive layer and is hardly deformed or molten by the heat, thereby maintaining the flatness and evenness of the base film. Especially, since the base film has a high tolerance to heat, so that the adhesive layer is prevented from retaining on the underside of a die. The expandability thereof can also satisfy the needs for die separation. Moreover, the base film is additionally added with metallic material having high thermal conductivity, so as to rapidly dissipate the heat generated by a die into environment. The heat will not be constrained within a limited area, thereby protecting the base film from any damage caused by local over-temperature. In the case of testing a semiconductor die with electrodes on separate faces, an electrically conductive adhesive may be selected to serve as the adhesive layer described herein, so that the die is secured in position while being tested by establishing electrical contact with the lower electrode of the die. The invention has successfully achieved the objects described above accordingly.

Especially, the terminal device according to the invention is simple in circuit structure and presents advantages of low manufacture cost and compact size, so that the portability of the electronic appliance coupled with the terminal device is not adversely affected. The invention enables users to acquire appropriate terminal devices for the precious electronic appliances of their own and utilize the same in conjunction with any types of power supplying apparatuses available in the market without worrying about any damage that may otherwise occur to their electronic appliances.

### BRIEF DESCRIPTION OF THE DRAWINGS

The above and other objects, features and effects of the invention will become apparent with reference to the following description of the preferred embodiments taken in conjunction with the accompanying drawings, in which:

FIG. 1 is a schematic diagram of a die formed with two electrodes on the same face;

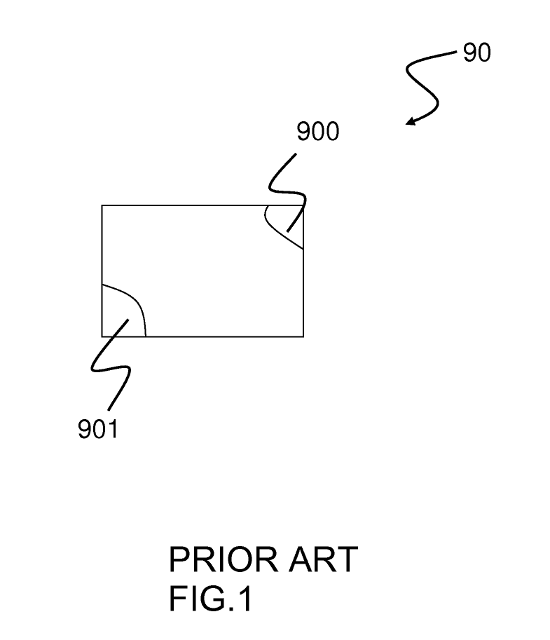

FIG. 2 is a schematic diagram illustrating the use of a blue tape to have dies separated;

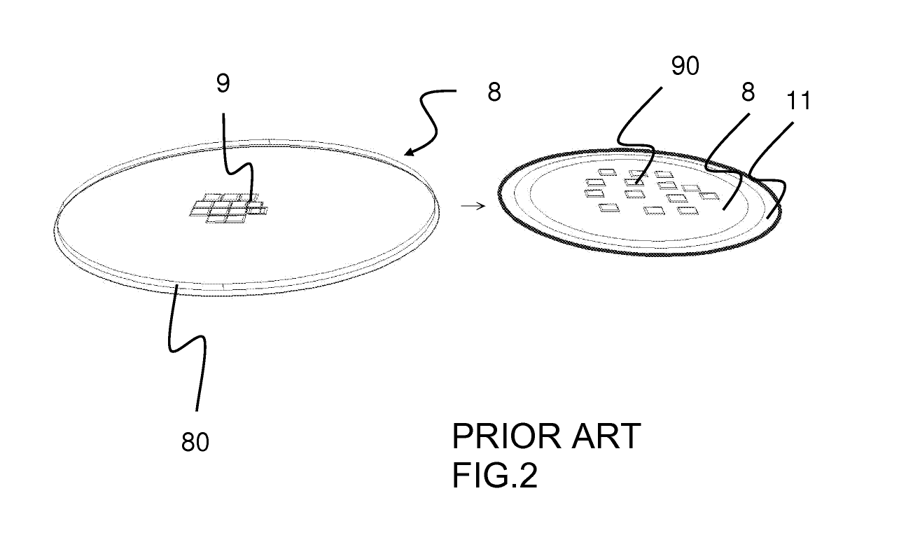

FIG. 3 is a schematic diagram illustrating the testing of a die formed with two electrodes on the same face;

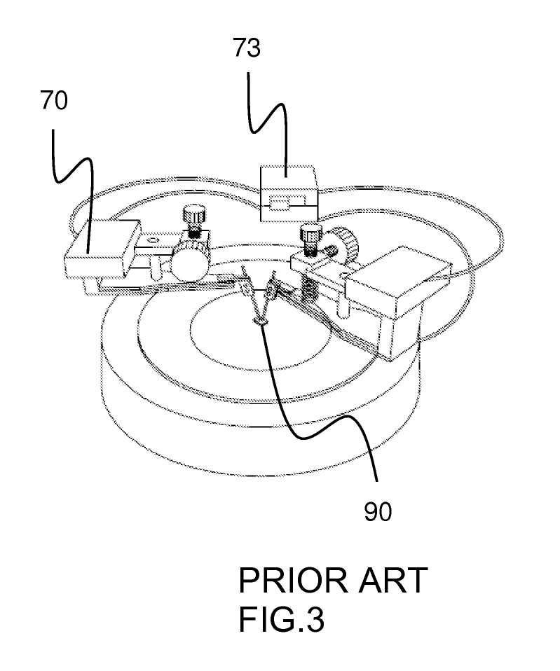

FIG. 4 is a schematic diagram of a semiconductor die formed with two electrodes on separate faces;

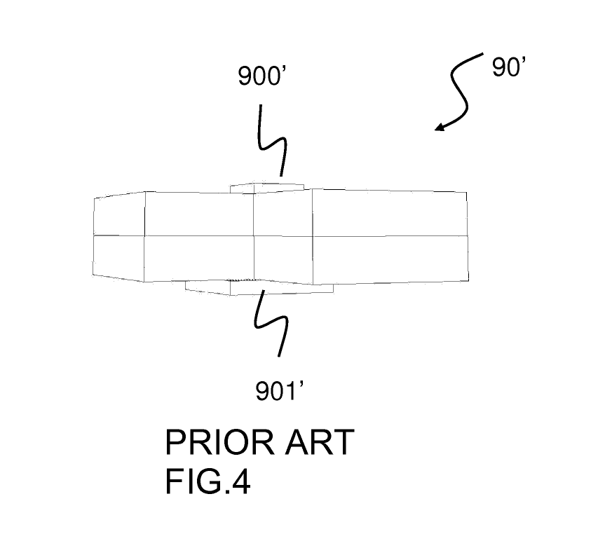

FIG. 5 is a schematic diagram illustrating the testing of a semiconductor die formed with two electrodes on separate faces;

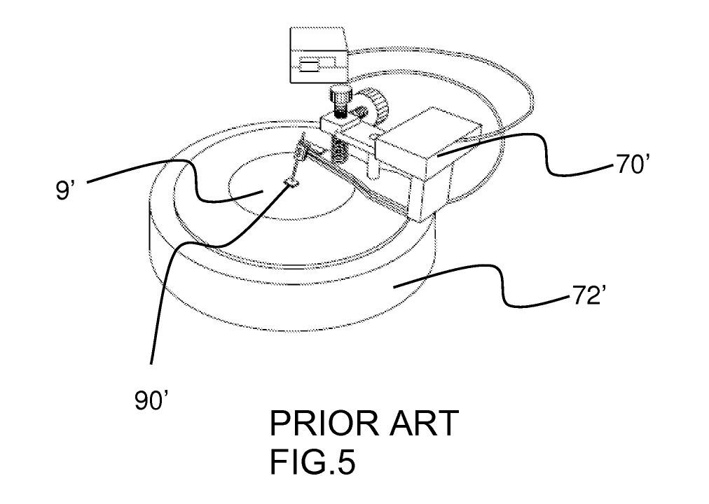

FIG. 6 is a schematic diagram illustrating a loading member according to the first preferred embodiment of the invention, on which a wafer is placed;

FIG. 7 is a schematic diagram showing that a die is placed on the loading member of the invention for being tested;

FIG. 8 is a schematic diagram illustrating a loading member according to the second preferred embodiment of the invention;

FIG. 9 is a schematic diagram showing the relationship of luminous efficiency versus temperature;

FIG. 10 is a schematic diagram showing the relationship of wavelength and emission power of light versus temperature;

FIG. 11 is a schematic diagram illustrating a loading member according to the third preferred embodiment of the invention;

FIG. 12 is a schematic diagram of a porous thermally conductive layer; and

FIG. 13 is a schematic diagram illustrating a test fixture according to the fourth preferred embodiment of the invention.

### DETAILED DESCRIPTION OF THE INVENTION

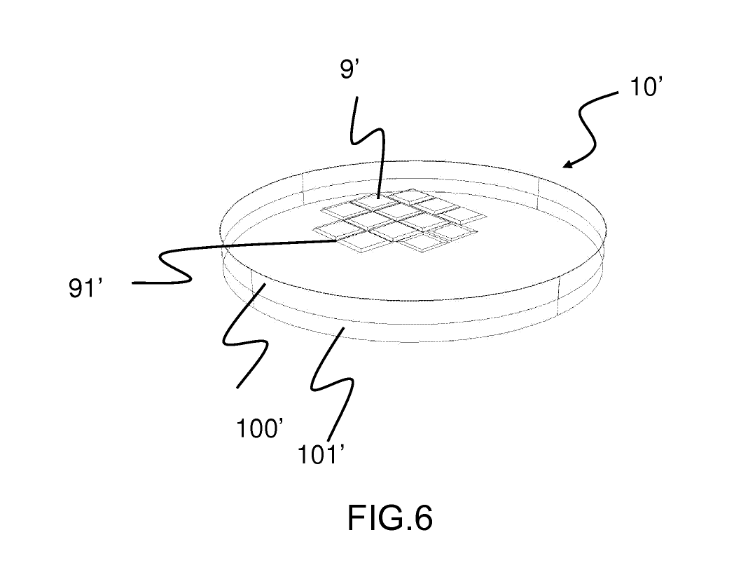

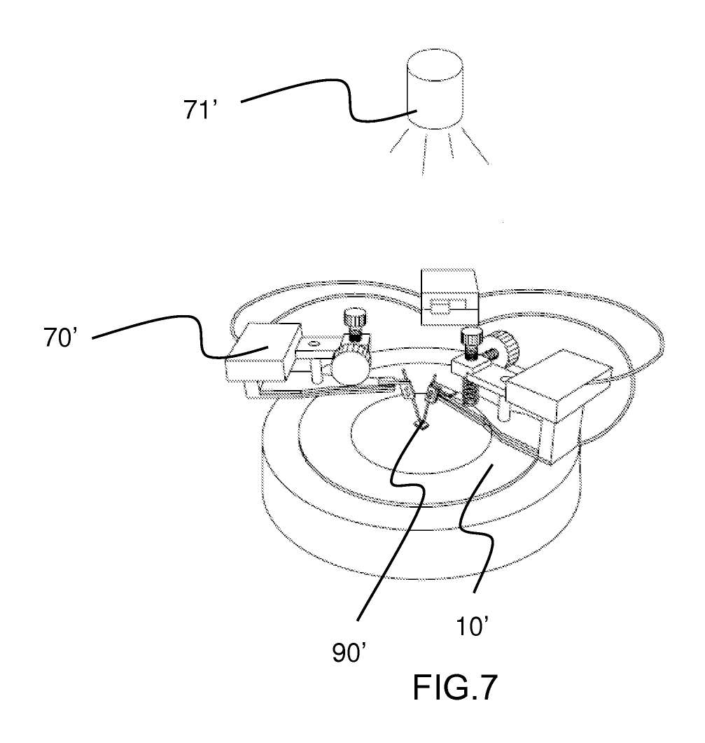

According to the first preferred embodiment of the invention shown in FIGS. 6 and 7, the die illustrated herein are formed with electrodes on the same face. As shown in FIG. 6, a wafer 9′ to be tested is positioned onto a loading member 10′, so that the wafer 9′ is intimately adhered at its underside to an adhesive layer 100′ of the loading member 10′, allowing the die electrodes to be exposed upwards. According to this embodiment, the loading member 10′ has a base film 101′ made of a polymeric material, preferably a polyethylene terephthalate (PET) material having a molecular weight of greater than 1×104 Dalton and a melting point of up to 256° C. and having excellent performance in insulation, stretching and toughness properties. Preferably, the adhesive layer 100′ is made of an acrylic-based electrically-conductive pressure sensitive adhesive (PSA) with a bonding strength of about 0.2 N/cm.

The wafer 9′, diced but not all the way through its thickness, is retained on the loading member 10′ by being adhered to the adhesive layer 100′. Since the loading member 10′ has a greater expandability as compared to the semiconductor die substrate 91′, the respective dies 90′ adhered to the loading member 10′ can be readily separated from one another by stretching the loading member 10′. When the respective dies 90′ are tested for electrical and optical properties, two probe elements 70′ are brought into contact with the electrodes of the respective dies 90′ as shown in FIG. 7, so that the dies 90′ are powered respectively to emit light. The instant temperature rise of a die 90′ supplied with electric power can be up to 300° C. Nevertheless, since the test takes no more than 250 ms to complete, the heat transfer from the die 90′ to the base film 101′ through the adhesive layer 100′ is so transient that the base film 101′ is heated to a temperature of less than or only slightly greater than 250° C. and cooled down immediately afterwards.

Since the temperature of the base film 101′ during the test is substantially lower than its melting point, the polymeric material that constitutes the base film 101′ can readily stand up to such a temperature, thereby ensuring that the loading member 10′ is hardly deformed or molten by the heat generated from the die 90′ and the flatness thereof is maintained. In other words, the respective dies 90′ adhered on the loading member 10′ are provided with electric power at a predetermined level, allowing the probe elements 70′ to smoothly contact the electrodes of the respective dies 90′ without facing any contact problem caused by the warp of the die carrier. The testing throughput is enhanced accordingly. Meanwhile, since the loading member 10′ is maintained horizontal, the light emission from the light-emitting face of the die 90′ under test is registered exactly on an optical detector 71′, without any angle offset between the light-emitting face of the die 90′ and the optical detector 71′ caused by warping of the die carrier. As such, the brightness and color temperature information and other data obtained during the test are ensured to be precise and accurate.

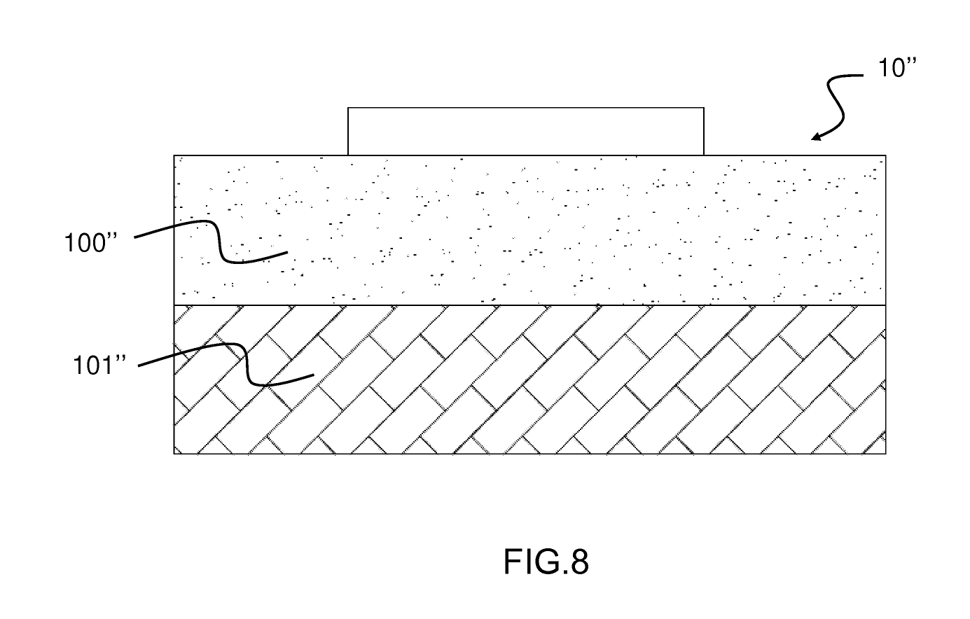

According to the second embodiment of the invention shown in FIG. 8, the base film 101″ of the loading member 10″ is made of a polymeric material and a metallic material, in which the polymeric material is preferably a polyethylene terephthalate (PET) material and the metallic material is preferably a copper powder with a thermal conductivity of up to 380 W/mK, a value that is much higher than 0.5 W/mK for polymeric materials, such as a PET material. The addition of a copper powder with higher heat dissipation capability into the PET polymeric material will produce a base film having an elevated thermal conductivity of 6 W/mK, while maintaining the tensile strength thereof at a level of approximately 44 N/cm which represents a maximum stretch increase of up to 66% at the fracture load. Preferably, the adhesive layer 100″ used herein is made of an acrylic-based electrically-conductive pressure-sensitive adhesive as described above.

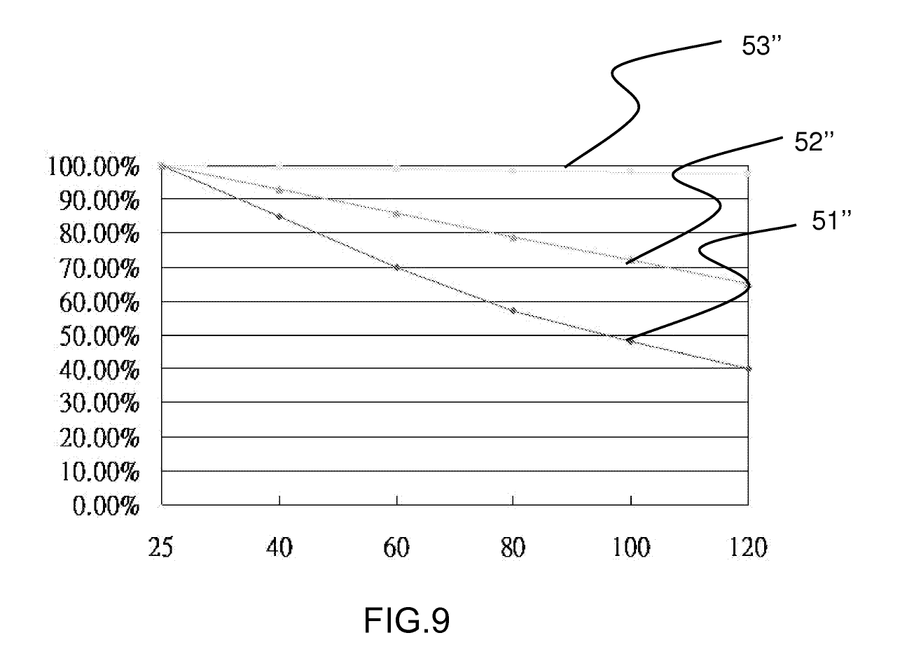

The junction temperature of a die is determined by the emission power of the die and the thermal conductivity and heat dissipation capability of the surrounded elements. In the case where the surrounded elements exhibit a poor thermal conductivity or the heat generation is higher than expected, the junction temperature will continuously increase. The temperature rise in the operation environment can seriously affect the optical and electrical properties of the LED die. The abscissa shown in FIG. 9 indicates the value of the junction temperature, while the luminous efficiency of three different visible-light LED dies at their central wavelengths is plotted in the ordinate. The plotted lines 51″, 52″ and 53″ represent the relationships of the luminous efficiency of the red, green and blue light versus the junction temperature, respectively, suggesting that the luminous efficiency of the LEDs of different colors will decay remarkably as the junction temperature increases. It further implies that the test data might possibly diverge from what happens in reality, if the temperature during the testing is substantially different from the working temperature.

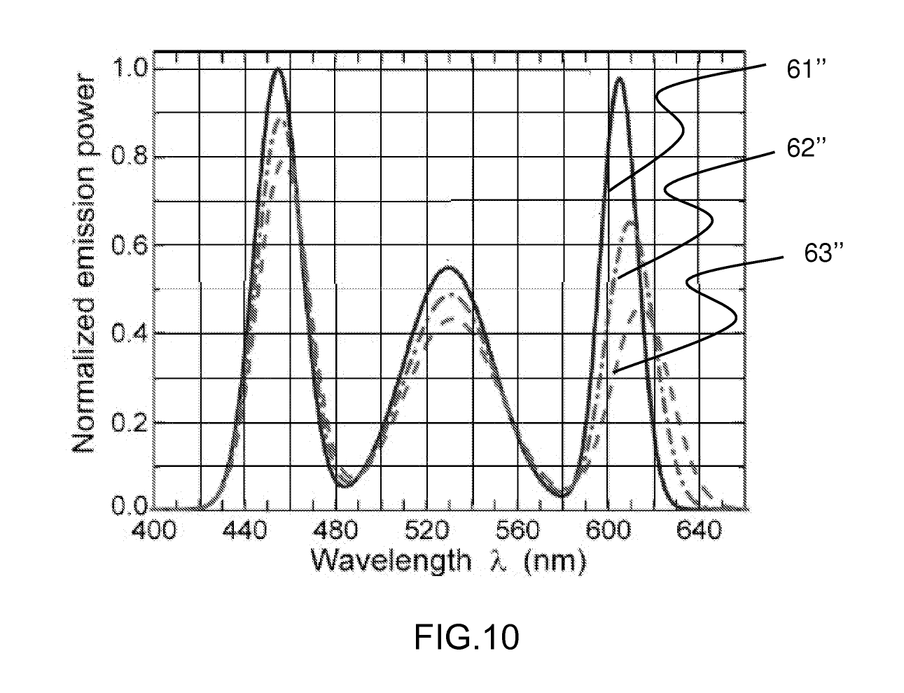

Furthermore, in the case where the red, green and blue LED dies with different central wavelengths as shown in FIG. 9 are integrated into a single white-light LED device, the emission power of the white-light LED device is plotted against wavelength at test temperatures of 20° C., 50° C. and 80° C., respectively. The plotted curves 61″, 62″ and 63″ are shown in FIG. 10, where the abscissa represents the wavelength of light and the coordinate corresponds to the emission power. The results indicate that as the temperature rises, the overall emission power decreases and the central wavelengths gradually shift towards longer wavelengths. And the red light diminishes more greatly as compared to the blue light. As such, the color temperature of the light emitted from the die is gradually shifted towards bluer color of lower temperature. The problems described here, if not taken care of by carefully controlling the test temperature at a level where the LED dies will actually face in real situation, will likely result in production of LED devices that fail to emit light with the predicted brightness and color temperature.

Therefore, during the process of testing the respective dies for electrical and optical properties, the test temperature has to be set at which the LED dies are lighted in real situation. The loading member disclosed herein can be imparted with different levels of thermal conductivity by being doped with metal powder in different proportions. Before the test is performed, the heat energy generated by the individual dies to be tested is estimated to acquire a reasonable operation temperature in real situation, from which the loading member is tailored such that it exhibits a suitable thermal conductivity for maintaining the thermal equilibrium temperature at an ideal level during the test. By using the loading member disclosed herein, the LED dies can be accurately tested for their optical and electrical properties under working conditions.

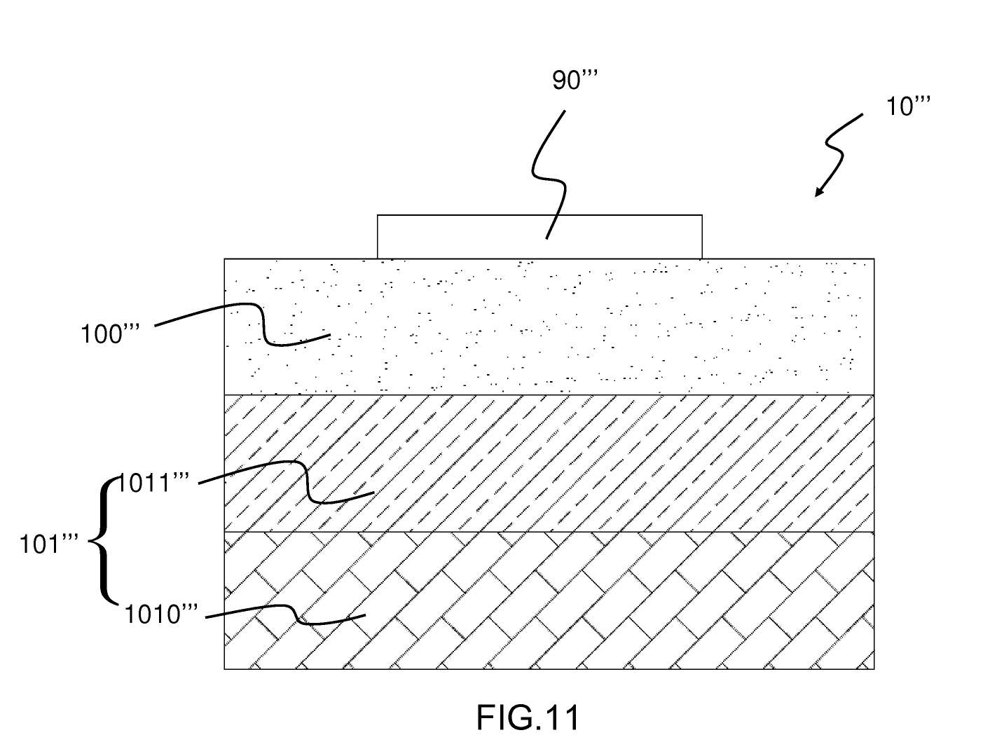

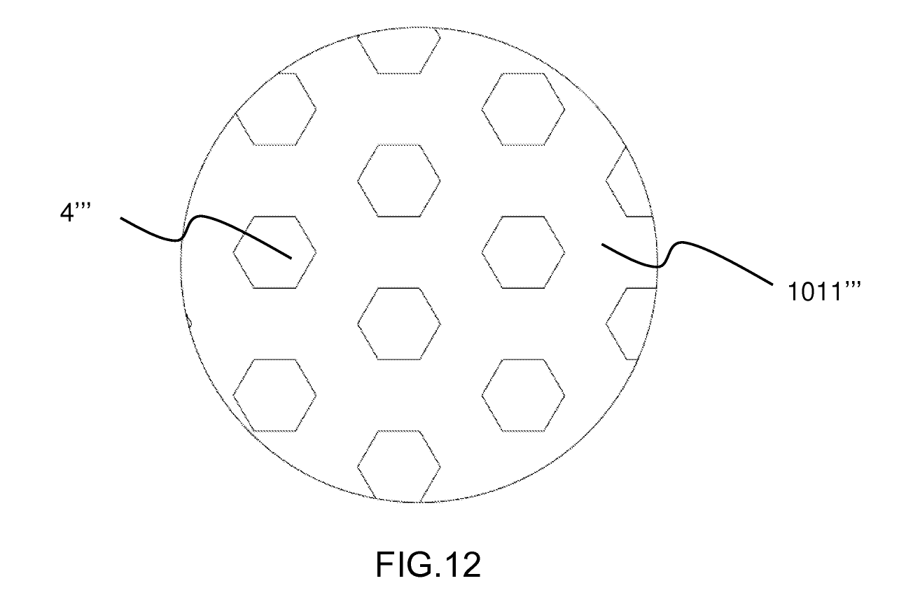

According to the third embodiment of the invention as shown in FIGS. 11 and 12, the base film 101′″ of the loading member 10′″ comprises a polyethylene terephthalate-based polymeric layer 1010′″ that serves to tolerate stretching, maintain the flatness and support the tested dies, and a thermally conductive layer 1011′″ made of aluminum powder. The thermally conductive layer 1011′″ appears to have a smooth outline like an ordinary aluminum foil, but the fact is that it is loose in texture due to being made of aluminum powder. Therefore, the thermally conductive layer 1011′″ is apt to create micro-pores 4′″ when the base film 101′″ is stretched, while retaining the thermal conductivity among aluminum powder, thereby spreading out the heat generated by the dies 90′″ across the loading member, enhancing the overall heat dissipation ability of the loading member and protecting the polymeric layer 1010′″ from high temperature impact. As a result, the problems attributed to residual adhesives and warping are considerably ameliorated.

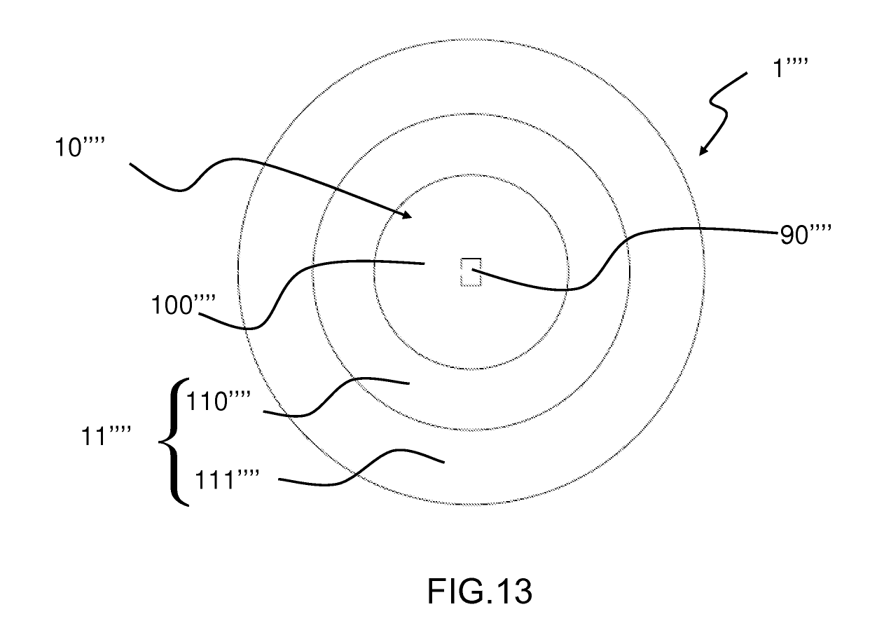

The loading member described above is disposed on a frame 11″″. According to the fourth embodiment of the invention as shown in FIG. 13, a test fixture 1″″ includes a loading member 10″″ whose base film is composed of a polymeric material and a metallic material. The polymeric material is a layer of a polyethylene terephthalate (PET) material and the metallic material is a thermally conductive layer of a powder of aluminum oxide molecules. The loading member 10″″ is provided with an adhesive layer which may by way of example be an electrically conductive adhesive layer 100″″ coated on the layer of aluminum molecules. The loading member 10″″ is stretched tightly to expand, so that the dies 90″″ adhered thereon are separated from one another. The rim of the loading member 10″″ is fixed in position by an inner frame member 110″″ of the frame 11″″, so that the loading member 10″″ is stretched tightly and clamped by the outer frame member 111″″ and the inner frame member 110″″ to constitute the test fixture 1″″. The individual dies secured on the test fixture 1″″ are now ready to be tested for optical and electrical properties. The invention enables the automatic separation and testing of the individual dies 90″″ accordingly.

While the invention has been described with reference to the preferred embodiments above, it should be recognized that the preferred embodiments are given for the purpose of illustration only and are not intended to limit the scope of the present invention and that various modifications and changes, which will be apparent to those skilled in the relevant art, may be made without departing from the spirit and scope of the invention.

What is claimed is:

1. A test fixture for testing a semiconductor die with its loading member maintained flat throughout the test, the test fixture being adapted for carrying a plurality of semiconductor dies to be tested by being supplied with electric power, the test fixture comprising:
a loading member, including:
an adhesive layer for adhering thereon the semiconductor die; and
a base film having a melting point substantially higher than a thermal equilibrium temperature thereof, wherein the thermal equilibrium temperature of the base film is achieved due to heat transfer from the semiconductor die under test to the base film via the adhesive layer; and
a frame for tightly stretching and fixing the loading member in position.

2. The test fixture according to claim 1, wherein the frame comprises:
an inner frame member for supporting and holding a rim of the loading member; and
an outer frame member complementary to the inner frame member for clamping and tightly stretching the loading member.

3. The test fixture according to claim 1, wherein the base film further comprises a polymeric layer having a greater expandability than a substrate of the semiconductor die, and a thermally conductive layer disposed between the adhesive layer and the polymeric layer, so that the heat generated by the semiconductor die under test is spread to a portion of the thermally conductive layer away from the semiconductor die under test.

4. The test fixture according to claim 3, wherein the thermally conductive layer is made of a powder of multiple thermally conductive molecules.

5. The test fixture according to claim 4, wherein the thermally conductive molecules are aluminum.

6. The test fixture according to claim 3, wherein the polymeric layer is a layer of polyethylene terephthalate (PET).

7. The test fixture according to claim 1, wherein the adhesive layer is an electrically conductive adhesive layer coated on the base film.
